(19) United States
(12) Patent Application Publication
(10) Pub. No.: US 2026/0305228 A1
(43) Pub. Date: Oct. 1, 2026

(54) DEVICE AND METHOD FOR MANUFACTURING DISPLAY PANEL, AND METHOD OF MANUFACTURING ELECTRONIC DEVICE INCLUDING DISPLAY PANEL

(71) Applicant: SAMSUNG DISPLAY CO., LTD., YONGIN-SI (KR)

(72) Inventors: Youngjin Son, YONGIN-SI (KR); Junhak Oh, YONGIN-SI (KR); Wunbong Tak, YONGIN-SI (KR)

(21) Appl. No.: 19/411,690

(22) Filed: Dec. 8, 2025

(30) Foreign Application Priority Data
Apr. 1, 2025 (KR) 10-2025-0042359

(51) Int. Cl. H10P 72/00; H10H 29/02; H10P 72/50; H10P 72/70

(52) U.S. Cl. CPC H10P 72/0442; H10H 29/02; H10P 72/0606; H10P 72/53; H10P 72/7442

(57) ABSTRACT

A device for manufacturing a display panel includes a first moving portion configured to move a first workpiece. A second moving portion is configured to move a second workpiece. A bonding portion includes an image-capturing element configured to capture images of the first workpiece and the second workpiece and a bonding element configured to bond the first workpiece and the second workpiece to each other.

### CROSS-REFERENCE TO RELATED APPLICATION

This application claims priority under 35 U.S.C. §119 to Korean Patent Application No. 10-2025-0042359, filed on Apr. 1, 2025 in the Korean Intellectual Property Office, the present disclosure of which is incorporated by reference in its entirety herein.

### 1. TECHNICAL FIELD

One or more embodiments relate to a device for manufacturing a display panel. Additionally, one or more embodiments relate to a method of manufacturing a display panel. Additionally, one or more embodiments relate to a method of manufacturing an electronic device including a display panel.

### 2. DISCUSSION OF RELATED ART

An electronic device may provide at least one still and/or moving image to a user by utilizing a display panel provided in the electronic device. The display panel may display visual data to the user. The display panel may provide the at least one still and/or moving image by using light-emitting diodes. The electronic device and display panel may be manufactured by disposing a plurality of layers on a substrate.

A manufacturing process of a display panel may include disposing a film, such as a polarizing film, on an unfinished product of the display panel. The film may be bonded (e.g., adhered) to the unfinished product of the display panel, such as via an adhesive layer provided underneath the film. To appropriately dispose the film, the film and the unfinished product of the display panel may be aligned with each other via prepared alignment marks. Alignment may be performed by capturing images of alignment marks provided in each of the film and the half-finished product of the display panel. When the alignment is performed by capturing images of the film and the half-finished product of the display panel in a separate image-capturing area, errors may occur while moving to a bonding area. Therefore, research is being conducted with respect to a structure for reducing or preventing such errors.

### SUMMARY

Additional aspects will be set forth in part in the description which follows and, in part, will be apparent from the description, or may be learned by practice of the presented non-limiting embodiments of the present disclosure.

According to one or more embodiments of the present disclosure, a device for manufacturing a display panel includes a first moving portion configured to move a first workpiece. A second moving portion is configured to move a second workpiece. A bonding portion includes an image-capturing element configured to capture images of the first workpiece and the second workpiece and a bonding element configured to bond the first workpiece and the second workpiece to each other.

In an embodiment, the bonding portion may further include a supporting element configured to secure the first workpiece.

In an embodiment, the supporting element may be disposed between the image-capturing element and the first workpiece and may transmit light. The image-capturing element may capture the images of the first workpiece and the second workpiece utilizing the light transmitted by the supporting element.

In an embodiment, the bonding portion may be disposed between the first moving portion and the second moving portion.

In an embodiment, the bonding element may be configured to be movable within the bonding portion.

In an embodiment, the image-capturing element may be configured to be attached to the bonding element and move with the bonding element.

In an embodiment, the image-capturing element and the bonding element may be disposed at a front end of the bonding portion and may be configured to reciprocate between the front end and a back end of the bonding portion.

In an embodiment, the image-capturing element may include a camera and the bonding element may include at least one roller.

In an embodiment, the device may further include a control portion configured to correct a position of the second workpiece relative to the first workpiece based on positions of the first workpiece and the second workpiece in the images of the first workpiece and the second workpiece captured by the image-capturing element.

According to one or more embodiments, a method for manufacturing a display panel includes moving a first workpiece to a bonding portion, moving a second workpiece to the bonding portion, capturing the first workpiece and the second workpiece with each other using an image-capturing element built into the bonding portion, aligning the first workpiece and the second workpiece with each other by correcting a position of the second workpiece relative to the first workpiece, and bonding the first workpiece and the second workpiece to each other using a bonding element built in the bonding portion while maintaining alignment positions of the aligned first workpiece and second workpiece.

In an embodiment, the bonding portion may further include a supporting element disposed between the filming element and the first workpiece, and the supporting element may transmit light such that the filming element may film the first workpiece and the second workpiece.

In an embodiment, the method may further include securing the first workpiece on a surface of the supporting element.

In an embodiment, the method may further include exposing an adhesive layer by removing a release film provided on a surface of the first workpiece secured on the first supporting element.

In an embodiment, in the bonding of the first workpiece and the second workpiece to each other, the first workpiece, the adhesive layer of the first workpiece, and the second workpiece may be compressed together.

In an embodiment, the method may further include peeling the bonded first workpiece and second workpiece from the supporting element.

In an embodiment, in the filming the first workpiece and the second workpiece, the filming element may be positioned at a front end of the bonding portion to film the first workpiece and the second workpiece.

In an embodiment, the bonding element may be configured to reciprocate between the front end and a back end of the bonding portion.

In an embodiment, the filming element may be configured to be attached to the bonding element and move with the bonding element.

In an embodiment, the aligning of the first workpiece and the second workpiece with each other and the bonding of the first workpiece and the second workpiece to each other may be performed in the bonding portion.

According to one or more embodiments, a method for manufacturing an electronic device includes manufacturing a display panel, and bonding the display panel with a processor. The manufacturing of a display panel includes moving a first workpiece to a bonding portion, moving a second workpiece to the bonding portion, capturing images of the first workpiece and the second workpiece using an image-capturing element built into the bonding portion, aligning the first workpiece and the second workpiece with each other by correcting a position of the second workpiece relative to the first workpiece, and bonding the first workpiece and the second workpiece to each other using a bonding element built into the bonding portion while maintaining alignment positions of the aligned first workpiece and second workpiece.

### BRIEF DESCRIPTION OF THE DRAWINGS

The above and other aspects, features, and advantages of certain non-limiting embodiments of the present disclosure will be more apparent from the following description taken in conjunction with the accompanying drawings, in which:

FIG. 1 is a schematic perspective view of a portion of a device for manufacturing a display panel, according to an embodiment of the present disclosure;

FIG. 2 is a schematic perspective view of a portion of a device for manufacturing a display panel, according to an embodiment of the present disclosure;

FIG. 3 is a block flow diagram of a method of manufacturing an electronic device, according to an embodiment of the present disclosure;

FIGS. 4A, 4B, 4C, 4D, 4E, 4G, and 4H are schematic cross-sectional views for explaining processes of a method of manufacturing a display panel, according to embodiments of the present disclosure;

FIG. 4F is a schematic plan view for explaining a process of a method of manufacturing a display panel, according to an embodiment of the present disclosure;

FIG. 5 is a block diagram of an electronic device according to an embodiment of the present disclosure;

FIG. 6, 7, and 8 are schematic views of electronic devices according to various embodiments of the present disclosure;

FIG. 9 is a schematic plan view of an electronic device according to an embodiment of the present disclosure; and

FIG. 10 is a cross-sectional view of a display panel according to an embodiment of the present disclosure.

### DETAILED DESCRIPTION OF EMBODIMENTS

As the present disclosure allows for various changes and numerous embodiments, certain non-limiting embodiments will be shown in the drawings and described in the detailed description. Effects and features of the present disclosure, and methods for achieving them will be clarified with reference to non-limiting embodiments described below in detail with reference to the drawings. However, the present disclosure is not limited to the following described embodiments and may be embodied in various forms.

Hereinafter, non-limiting embodiments will be described in detail with reference to the accompanying drawings, wherein the same or corresponding elements are denoted by the same reference numerals throughout and a repeated description thereof is omitted.

Throughout the present disclosure, the terms "first," "second," etc. may be used to describe various elements, but these elements should not be limited by these terms. These terms are only used to distinguish one element from another.

Throughout the present disclosure, the singular forms "a," "an," and "the" are intended to include the plural forms as well, unless the context clearly indicates otherwise.

Throughout the present disclosure, it will be understood that the terms "comprising," "including," and "having" are intended to indicate the existence of the features or elements described in the specification, and are not intended to preclude the possibility that one or more other features or elements may exist or may be added.

Throughout the present disclosure, it will be further understood that, when a layer, region, or component is referred to as being "on" another layer, region, or component, it may be directly on the other layer, region, or component, or may be indirectly on the other layer, region, or component with intervening layers, regions, or components therebetween. When a layer, region, or component is referred to as being "directly on" another layer, no intervening elements may be present.

Sizes of components in the drawings may be exaggerated or reduced for convenience of explanation. For example, since sizes and thicknesses of components in the drawings may be arbitrarily shown for convenience of explanation, embodiments of the present disclosure are not necessarily limited thereto.

When a certain embodiment may be implemented differently, a specific processing order may be different from the described order. For example, two consecutively described processes may be performed substantially at the same time or may be performed in an order opposite to the described order.

Throughout the present disclosure, "A and/or B" is used to select only A, select only B, or select both A and B. Throughout the present disclosure, "at least one of A or B" is used to select only A, select only B, or select both A and B.

Throughout the present disclosure, when a layer, a region, a component, etc. are (e.g., electrically) connected to each other, the layer, the region, and the components may be directly (e.g., and electrically) connected to each other and/or the layer, the region, and the components may be indirectly (e.g., and electrically) connected to each other with other layers, regions and components interposed therebetween.

The x axis, the y axis, and the z axis are not necessarily limited to the three axes on a Cartesian coordinate system, and may be interpreted in a broader sense. For example, the x axis, the y axis, and the z axis may be perpendicular to each other, but may also refer to different axes that intersect each other but are not perpendicular to each other.

The present disclosure concerns a device for manufacturing a display panel that includes a bonding portion having both an image-capturing element and a bonding element integrated therein. The image-capturing element captures images of a first workpiece and a second workpiece. The bonding element bonds the first workpiece and the second workpiece to each other.

The second workpiece may be aligned with the first workpiece based on the images captured by the image-capturing element. Since the alignment and bonding of the first workpiece and the second workpiece are performed in a same space, unnecessary movements are eliminated between the alignment and bonding processes and errors in the alignment and bonding of the first workpiece and the second workpiece to each other may be avoided.

The positioning of the first workpiece and then performing alignment by correcting a position of the second workpiece based on the position of the first workpiece reduces the number of procedures of alignment and prevents errors in the alignment and bonding processes.

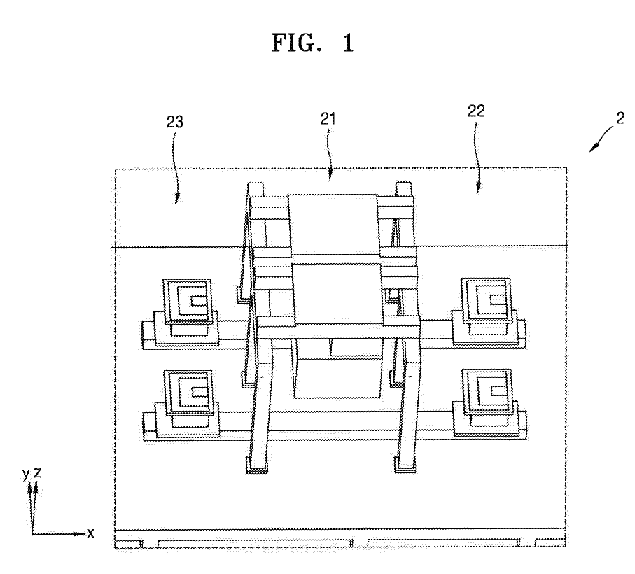

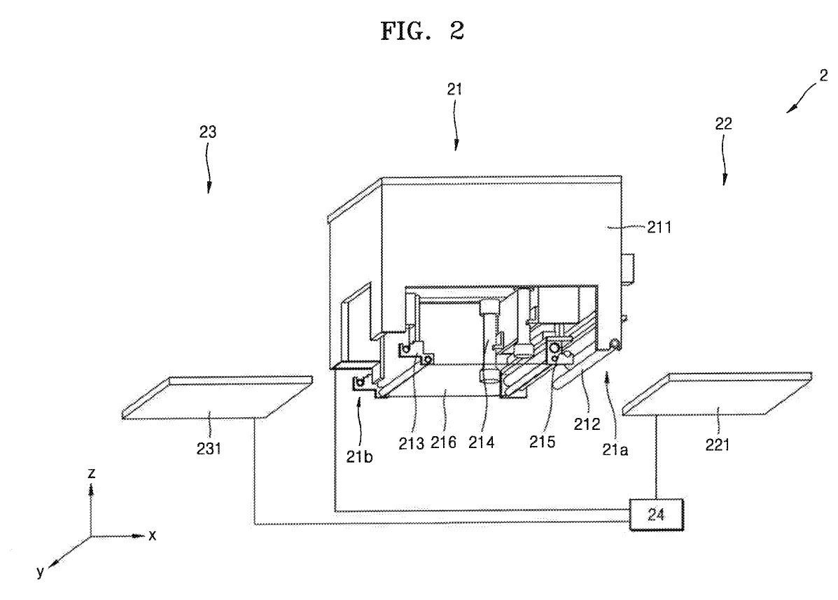

FIG. 1 is a schematic perspective view of a portion of a device for manufacturing a display panel, according to an embodiment. FIG. 2 is a schematic perspective view of a portion of a device for manufacturing a display panel, according to an embodiment.

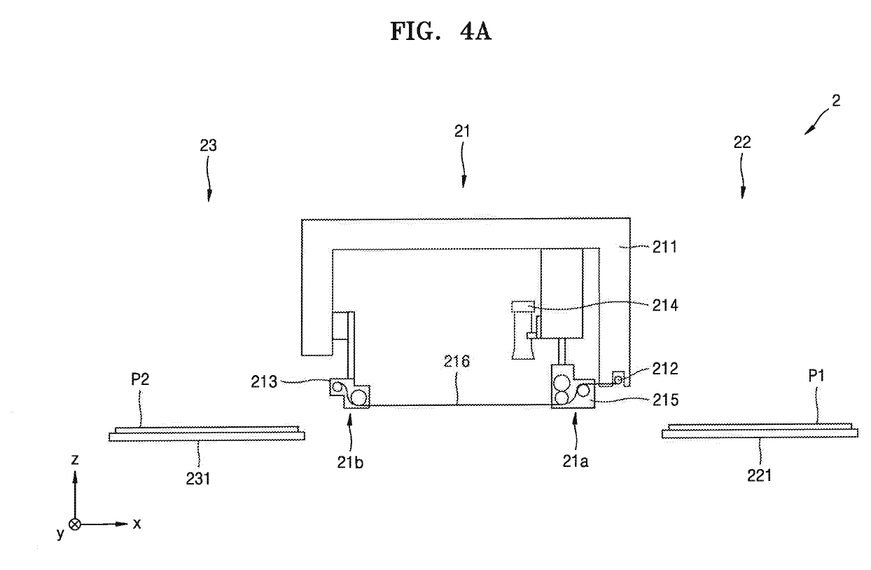

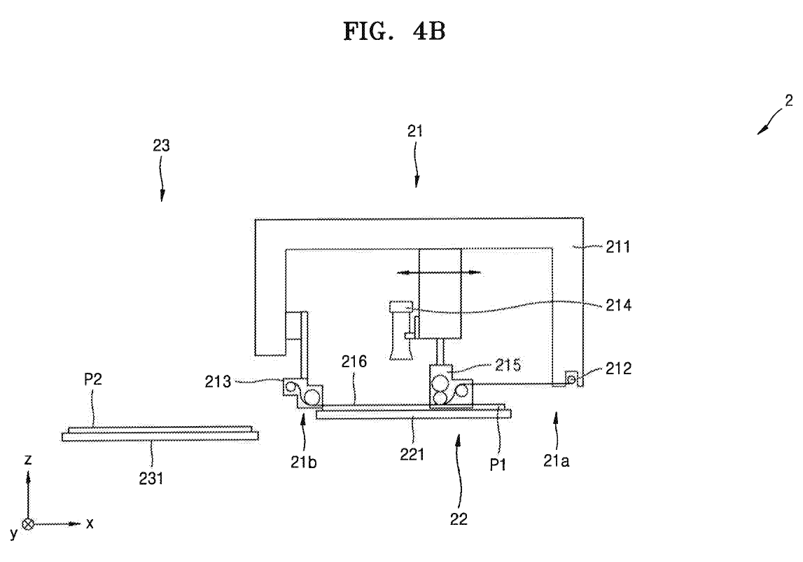

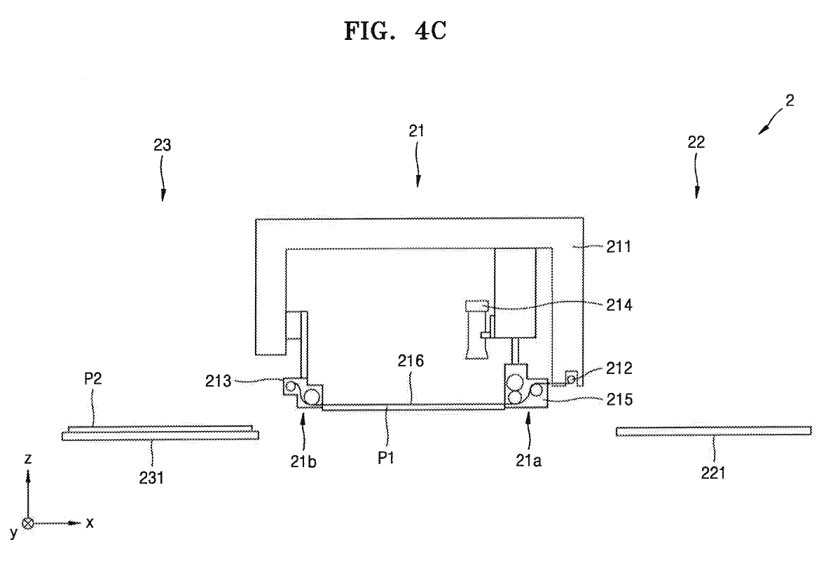

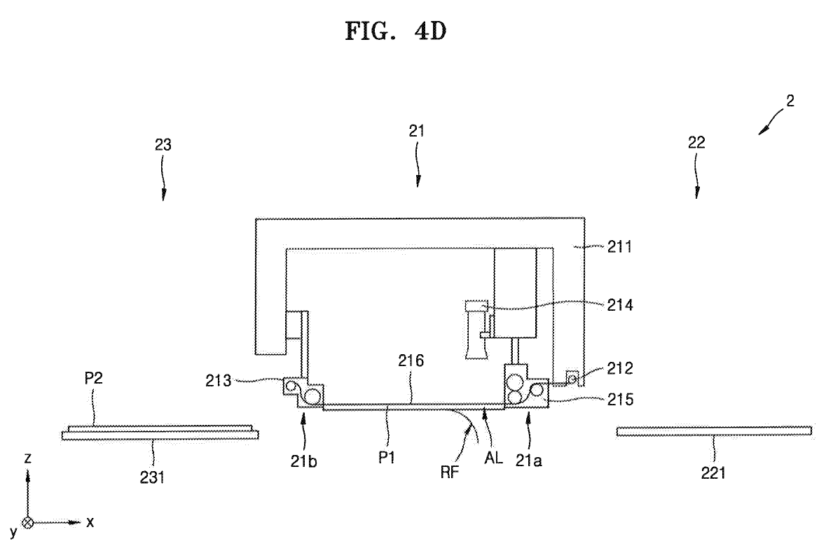

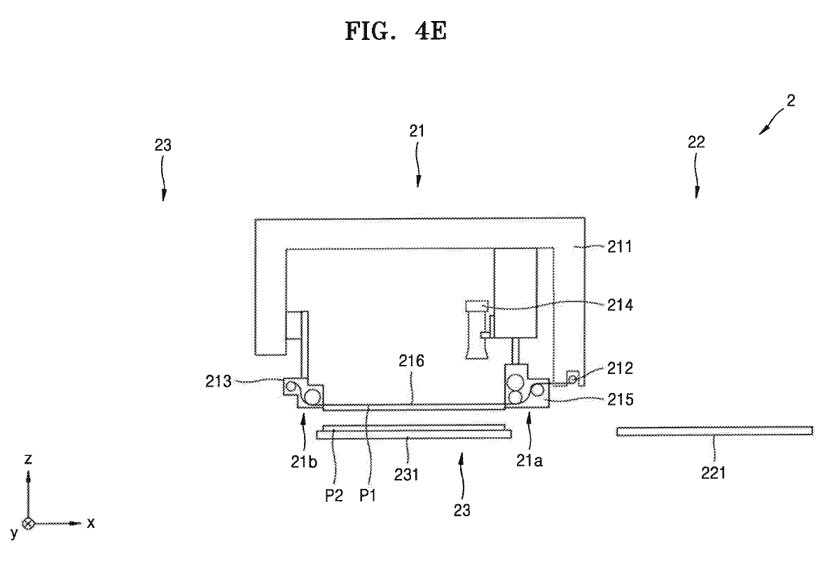

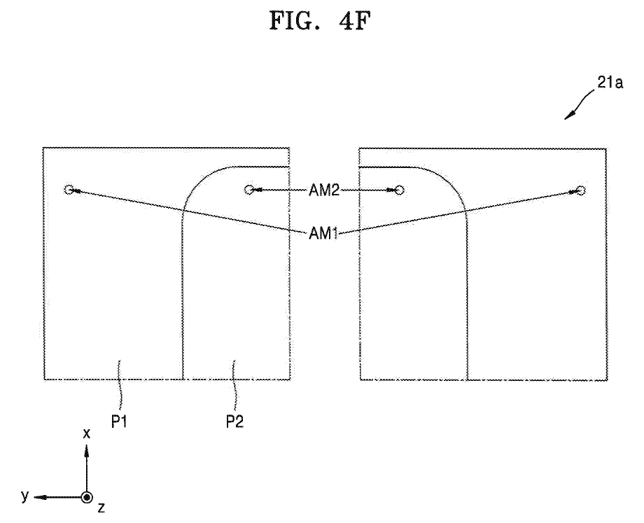

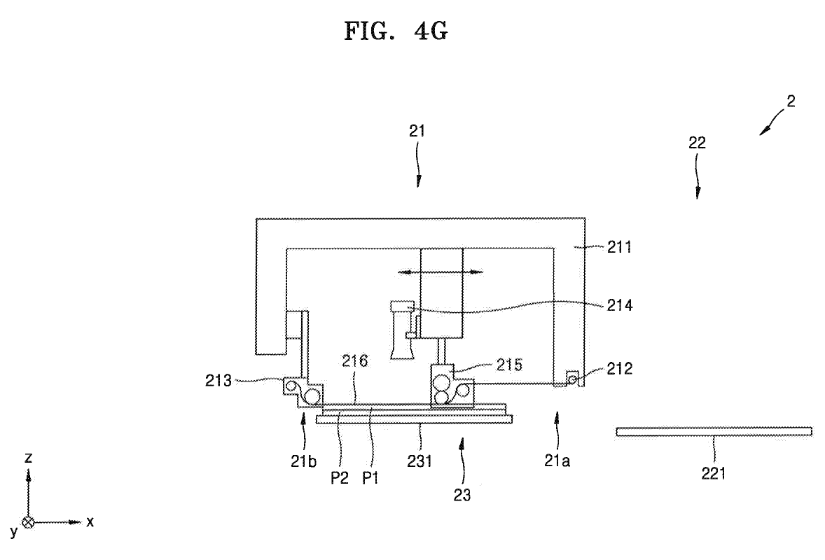

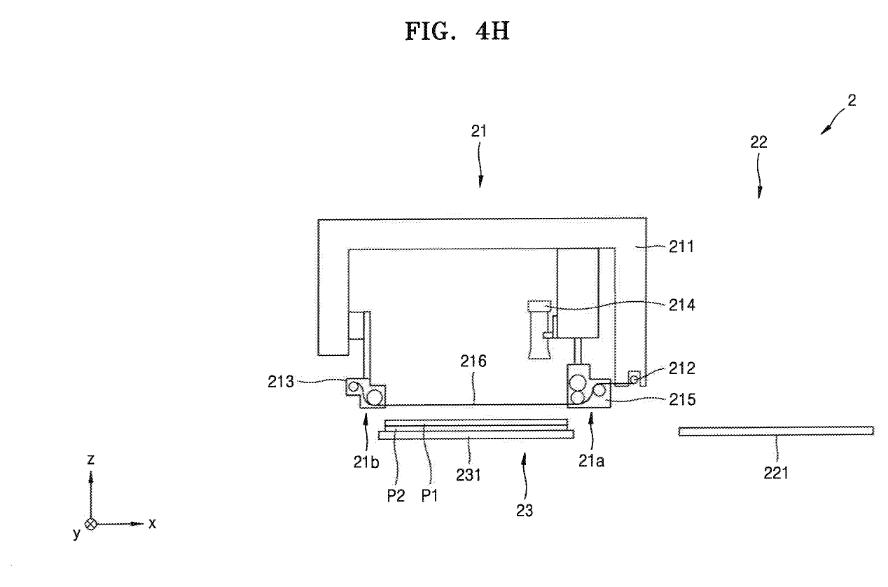

Referring to FIGS. 1 and 2, in an embodiment a device 2 for manufacturing a display panel may include a bonding portion 21, a first moving portion 22, a second moving portion 23, and a control portion 24. In an embodiment, a first workpiece P1 and a second workpiece P2 (refer also to FIG. 4A herein) may be bonded (e.g., adhered) to each other in the bonding portion 21. The first moving portion 22 may secure and move the first workpiece P1. The second moving portion 23 may secure and move the second workpiece P2.

In an embodiment, the first moving portion 22 may include a first stage 221 supporting the first workpiece P1. In an embodiment, the first workpiece P1 may be secured on the first stage 221 and be moved to the bonding portion 21 with the first stage 221 secured thereon. In an embodiment, the device 2 for manufacturing a display panel may include any suitable means (e.g., a robot arm) for loading/unloading the first workpiece P1 on/from the first stage 221. In an embodiment, the first moving portion 22 of the device 2 for manufacturing a display panel may include any suitable means (e.g., an actuator, a rail, and/or a linear motion (LM) guide) for moving the first stage 221.

In an embodiment, the second moving portion 23 may include a second stage 231 supporting the second workpiece P2. In an embodiment, the second workpiece P2 may be secured on the second stage 231 and be moved to the bonding portion 21 with the second stage 231 secured thereon. In an embodiment, the device 2 for manufacturing a display panel may include any suitable means (e.g., a robot arm) for loading/unloading the second workpiece P2 on/from the second stage 231. In an embodiment, the second moving portion 23 of the the device 2 for manufacturing a display panel may include any suitable means (e.g., an actuator, a rail, and/or a LM guide) for moving the second stage 231.

The bonding portion 21 may be disposed between the first moving portion 22 and the second moving portion 23 (e.g., in the x-axis direction). In an embodiment, the bonding portion 21 may include a frame 211, a first fastening element 212, a second fastening element 213, an image-capturing element 214, a bonding element 215, and a supporting element 216.

The frame 211 may form the general external structure of the bonding portion 21, and other elements of the bonding portion 21 may be connected to the frame 211. In an embodiment, each of the first fastening element 212, the second fastening element 213, the image-capturing element 214, the bonding element 215, and the supporting element 216 may be connected to the frame 211.

In an embodiment, the first fastening element 212 and the second fastening element 213 may be respectively disposed at two ends (e.g., opposite ends in the x-axis direction) of the bonding portion 21. In an embodiment, the first fastening element 212 may be disposed at the front end 21a (e.g., a first end in the x-axis direction) of the bonding portion 21. In an embodiment, the second fastening element 213 may be disposed at the back end 21b (e.g., a second end in the -x-axis direction) of the bonding portion 21. In an embodiment, the front end 21a of the bonding portion 21 may be located in a first axis (e.g., x-axis) direction of the back end 21b.

In an embodiment, the supporting element 216 may be fastened to the first fastening element 212 and the second fastening element 213. In an embodiment, two ends (e.g., opposite ends along the x-axis direction) of the supporting element 216 may be respectively fastened to the first fastening element 212 and the second fastening element 213. In an embodiment, the supporting element 216 may extend along the first axis (e.g., the x-axis) from the front end 21a (e.g., a first end) to the back end 21b (e.g., a second end) of the bonding portion 21. In an embodiment, the supporting element 216 may be provided in the form of a film, such as a transparent film. In an embodiment, a top surface and a bottom surface of the supporting element 216 may extend in a plane parallel to the first axis (e.g., the x-axis) and a second axis (e.g., the y-axis), for example, on the xy plane. In an embodiment, the top surface of the supporting element 216 may face in a third axis (e.g., the z-axis) direction, and the bottom surface of the supporting element 216 may face in a -z-axis direction. In an embodiment, the supporting element 216 may provide a surface on which the first workpiece P1 may be secured on. In an embodiment, the first workpiece P1 may be secured on the bottom surface of the supporting element 216.

The bonding element 215 and the image-capturing element 214 may be disposed on the supporting element 216. In an embodiment, the supporting element 216 may be disposed between the image-capturing element 214 and the first workpiece P1 (e.g., in the z-axis direction). In an embodiment, the supporting element 216 may transmit light so that the image-capturing element 214 may capture images of the first workpiece P1. In an embodiment, the bonding element 215 may be movable within the bonding portion 21. In an embodiment, the bonding element 215 may be translationally movable (e.g., reciprocate) between the front end 21a and the back end 21b of the bonding portion 21. In an embodiment, the image-capturing element 214 may be bonded to the bonding element 215 and may be movable with the bonding element 215. For example, in an embodiment, the image-capturing element 214 may also be translationally movable (e.g., reciprocate) between the front end 21a and the back end 21b of the bonding portion 21. In an embodiment, the image-capturing element 214 and the bonding element 215 may be movable together within the bonding portion 21. In an embodiment, the bonding portion 21 may include any suitable means (e.g., an actuator, a rail, and/or a LM guide) for moving the bonding element 215 and the image-capturing element 214. FIG. 2 illustrates an embodiment in which the bonding element 215 and the image-capturing element 214 are located at the front end 21a of the bonding portion 21. In an embodiment, the bonding element 215 may include means (e.g., at least one roller) for bonding the first and second workpieces P1 and P2 to each other. In an embodiment, the image-capturing element 214 may include means (e.g., a camera) for capturing images of, for example, alignment marks of, the first and second workpieces P1 and P2. In an embodiment, the image-capturing element 214 may be built into (e.g., integrated into) the bonding portion 21, for example the bonding element 215. The images captured by the image-capturing element 214 may be one or more still and/or moving images.

The control portion 24 may be connected to (e.g., electrically connected thereto) the bonding portion 21, the first moving portion 22, and the second moving portion 23. The control portion 24 may control the image-capturing element 214 and the bonding element 215 of the bonding portion 21. In an embodiment, the control portion 24 may use the image-capturing element 214 to capture images of the first and second workpieces P1 and P2. The control portion 24 may control the first moving portion 22 and/or the second moving portion 23 by using results of the images of the above-mentioned image capturing. In an embodiment, the control portion 24 may move and position the first stage 221 with the first workpiece P1 and/or the second stage 231 with the second workpiece P2 such that the first and second workpieces P1 and P2 are aligned in predetermined relative positions. In an embodiment, the control portion 24 may control the bonding element 215 such that the first workpiece P1 is bonded onto the supporting element 216 or the second workpiece P2 is bonded onto the first workpiece P1.

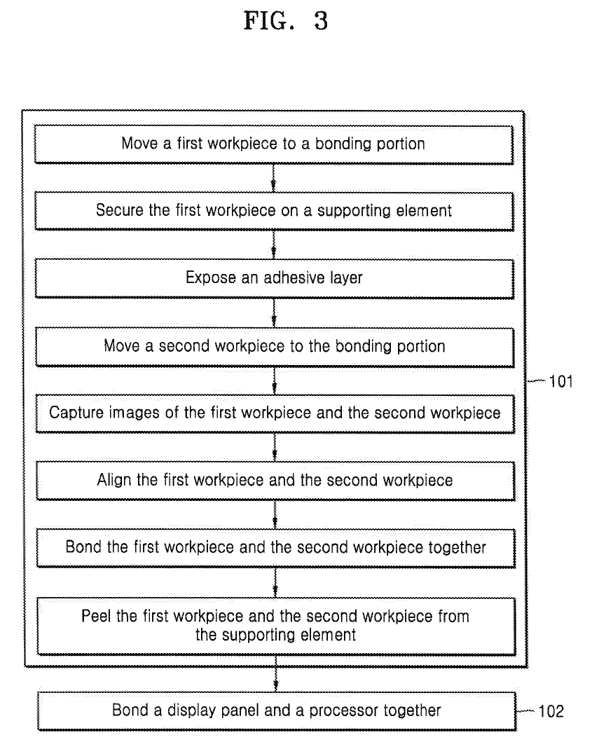

FIG. 3 is a block flow diagram of a method of manufacturing an electronic device according to an embodiment. FIGS. 4A, 4B, 4C, 4D, 4E, 4G, and 4H are schematic cross-sectional views for explaining processes of a method of manufacturing a display panel according to embodiments of the present disclosure. FIG. 4F is a schematic plan view for explaining a process of a method of manufacturing a display panel according to an embodiment.

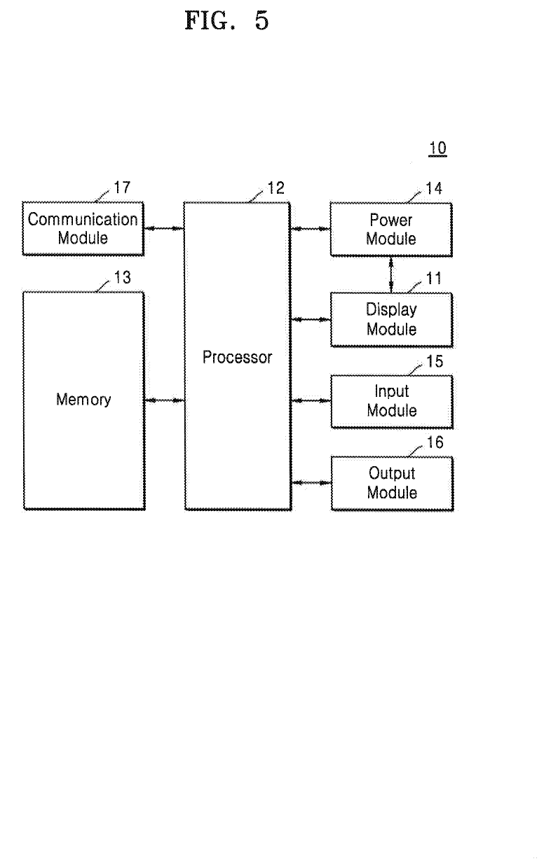

Referring to FIG. 3, a method of manufacturing an electronic device may include a process 101 of manufacturing a display panel, and a process 102 of bonding the display panel with a processor. The method of manufacturing an electronic device may further include one or more processes of bonding components of the electronic device other than the processor (refer to FIG. 5) with the display panel.

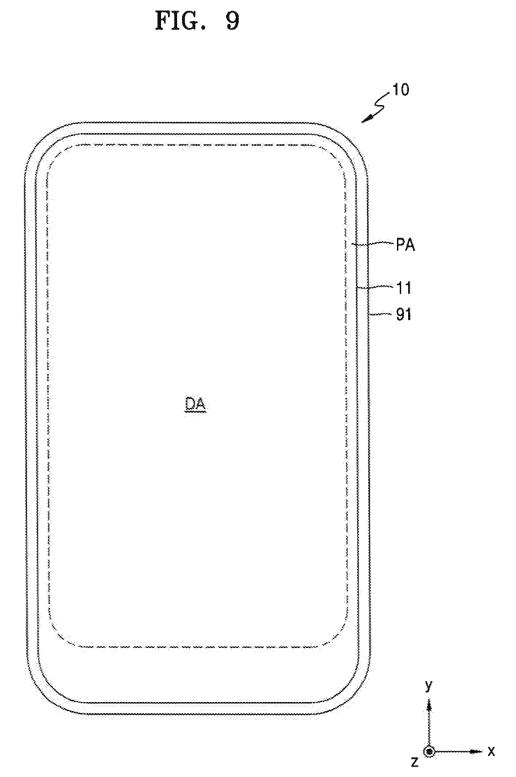

The process 101 of manufacturing a display panel and a corresponding method of manufacturing a display panel is described in detail herein with reference to FIGS. 3 and 4A to 4H. In the following description, the first workpiece P1 and the second workpiece P2 may be parts of a display panel 11 that are subject to processing by the device 2 for manufacturing a display panel (refer also to FIG. 9 hereinafter). In an embodiment, the second workpiece P2 may be an unfinished product (e.g., a half-finished) of the display panel 11 in the process of being manufactured, and the first workpiece P1 may be a component of the display panel 11 to be additionally disposed on the second workpiece P2. In an embodiment, the second workpiece P2 may be a unfinished product of the display panel 11, and the first workpiece P1 may be a film (e.g., polarizing film). In an embodiment, a process of bonding the first workpiece P1 and the second workpiece P2 may be part of the process 101 of manufacturing a display panel.

Referring to FIGS. 3 and 4A, the process 101 of manufacturing a display panel or the method of manufacturing a display panel may include a process of preparing the first workpiece P1 and the second workpiece P2. The first workpiece P1 may be secured on the first stage 221. The first moving portion 22 may include means (e.g., a robot arm) for securing the first workpiece P1 on the first stage 221. In an embodiment, the first workpiece P1 and the first moving portion 22 may be disposed at the front end 21a (e.g., in the x-axis direction) of the bonding portion 21.

The process 101 of manufacturing a display panel or the method of manufacturing a display panel may include a process of moving the first workpiece P1 to the bonding portion 21.

Referring to FIGS. 3, 4B, and 4C, the process 101 of manufacturing a display panel or the method of manufacturing a display panel may include a process of securing the first workpiece P1 on the supporting element 216.

In an embodiment, the first workpiece P1 may be moved with the first stage 221 by the first moving portion 22 to overlap the supporting element 216 of the bonding portion 21 (e.g., in the -z direction). In an embodiment, the first stage 221 may rise with the first workpiece P1, and the first workpiece P1 may be brought into direct contact with the supporting element 216. In an embodiment, while maintaining the direct contact of the first workpiece P1 with the supporting element 216, the bonding element 215 may bond the first workpiece P1 onto the supporting element 216. In an embodiment, the bonding element 215 may reciprocate between the front end 21a and the back end 21b of the bonding portion 21 and bond (e.g., attach) the first workpiece P1 onto the supporting element 216 by applying pressure to the first workpiece P1 and the supporting element 216 by means of at least one roller. In an embodiment, while the bonding element 215 performs the above-mentioned reciprocating movement, the image-capturing element 214 may move along with (e.g., reciprocate with) the bonding element 215. In an embodiment, while the bonding element 215 applies pressure to the supporting element 216 and the first workpiece P1, the first stage 221 may fasten (e.g., secure) the first workpiece P1 in place. In an embodiment, the first workpiece P1 may be bonded (e.g., attached or secured) to a surface (e.g., a bottom surface) of the supporting element 216. In an embodiment, the first stage 221 may then be sent back to the original position (e.g., to the front end 21a of the bonding portion 21).

Referring to FIGS. 3 and 4D, in an embodiment the process 101 of manufacturing a display panel or the method of manufacturing a display panel may include a process of exposing an adhesive layer AL of the first workpiece P1. In an embodiment, the first workpiece P1 may include an adhesive layer AL on a surface (e.g., a bottom surface). In an embodiment, the first workpiece P1 may include a release film RF covering the adhesive layer AL. In an embodiment, the adhesive layer AL and the release film RF may be disposed on an opposite surface (e.g., a bottom surface) of a surface (e.g., a top surface) of the first workpiece P1 contacting a surface (e.g., a bottom surface) of the supporting element 216. In an embodiment, while the first workpiece P1 is secured on the supporting element 216, the release film RF of the first workpiece P1 may be removed and the adhesive layer AL may be exposed. In an embodiment, the release film RF may be removed via any suitable means (e.g., a robot arm).

Referring to FIGS. 3 and 4E, the process 101 of manufacturing a display panel or the method of manufacturing a display panel may further include a process of moving the second workpiece P2 to the bonding portion 21.

The second workpiece P2 may be secured on the second stage 231. In an embodiment, the second moving portion 23 may include means (e.g., a robot arm) for securing the second workpiece P2 on the second stage 231. In an embodiment, the second workpiece P2 and the second moving portion 23 may be disposed at the back end 21b (e.g., in the x-axis direction) of the bonding portion 21. The second stage 231 may pass through the back end 21b of the bonding portion 21 such that the second workpiece P2 overlaps (e.g., in the -z-axis direction) the supporting element 216 and the first workpiece P1 secured to the supporting element 216.

Referring to FIGS. 3, 4E, and 4F, the process 101 of manufacturing a display panel or the method of manufacturing a display panel may include a process of capturing images of the first workpiece P1 and the second workpiece P2 by using the image-capturing element 214 built into (e.g., integrated in) the bonding portion 21. FIG. 4F illustrates a plan view of the first workpiece P1 and second workpiece P2 captured by the image-capturing element 214.

In an embodiment, the first workpiece P1 may include a plurality of first alignment marks AM1 and the second workpiece P2 may include a plurality of second alignment marks AM2. While FIG. 4F shows that the plurality of first alignment marks AM1 and the plurality of second alignment marks AM2 each include two circular marks, embodiments of the present disclosure are not necessarily limited thereto and the number of the alignment marks and the shape of the alignment marks may vary. In an embodiment, the plurality of first alignment marks AM1 may be disposed at a portion of the first workpiece P1 adjacent to the front end 21a of the bonding portion 21. In an embodiment, the plurality of second alignment marks AM2 may be disposed at a portion of the second workpiece P2 adjacent to the front end 21a of the bonding portion 21. In an embodiment, the image-capturing element 214 may be positioned at the front end 21a of the bonding portion 21 and capture images of the first workpiece P1 and the second workpiece P2.

In an embodiment, the supporting element 216 may transmit light such that the image-capturing element 214 may capture images of the first workpiece P1 and the second workpiece P2. In an embodiment, the supporting element 216 may be provided as a transparent film. In an embodiment, the first workpiece P1 may transmit light such that the image-capturing element 214 may capture images of the second workpiece P2. In an embodiment, the first workpiece P1 may be provided as a transparent film (e.g., a polarizing film). Accordingly, although the supporting element 216 is located between the first and second workpieces P1 and P2 and the image-capturing element 214 (e.g., in the z-axis direction), the image-capturing element 214 may capture images of the first and second workpieces P1 and P2 (e.g., the first and second alignment marks AM1 and AM2) without difficulties. For example, the image-capturing element 214 may utilize the light transmitted through the supporting element 216 which may be a transparent film to capture the images of the first workpiece P1 and the second workpiece P2. The image-capturing element 214 may utilize the light transmitted through the supporting element 216 and the first workpiece P1 to capture the images of the second workpiece P2.

The process 101 of manufacturing a display panel or the method of manufacturing a display panel may include a process of aligning the first workpiece P1 and the second workpiece P2. In an embodiment, alignment of the first workpiece P1 and the second workpiece P2 may be performed by aligning the plurality of first alignment marks AM1 and the plurality of second alignment marks AM2. In an embodiment, relative positions of the plurality of first alignment marks AM1 and the plurality of second alignment marks AM2 for aligning the first workpiece P1 and the second workpiece P2 may be predetermined or pre-designed. In an embodiment, the relative positions may include complete overlapping, partial overlapping, spacing by certain distances along a certain axis (e.g., the x axis and/or the y axis), etc.

In an embodiment, the alignment of the first workpiece P1 and the second workpiece P2 may be performed based on the first workpiece P1. For example, the plurality of second alignment marks AM2 and furthermore the second workpiece P2 may be aligned based on the plurality of first alignment marks AM1. In an embodiment, the first workpiece P1 may be secured onto the supporting element 216 without a specific positioning basis. The second workpiece P2 may then be introduced to the bonding portion 21 and images of the first workpiece P1 and the second workpiece P2, for example, the plurality of first alignment marks AM1 and the plurality of second alignment marks AM2, may be captured by the image-capturing element 214. In an embodiment, a position of the first workpiece P1 (e.g., on the xy plane), such as a position of the plurality of first alignment marks AM1 (e.g., on the xy plane) may be retained while the second workpiece P2 is moved into alignment according to the predetermined or pre-designed relative position. For example, a position of the plurality of second alignment marks AM2, such as a position of the second workpiece P2, may be corrected based on the position of the plurality of first alignment marks AM1. The above-mentioned predetermined or pre-designed relative positions may be utilized for such correction of positions.

As a comparative example, in a case of an embodiment in which the first workpiece P1 and the second workpiece P2 are aligned based on a third alignment mark by aligning the plurality of first alignment marks AM1 based on the separately provided third alignment mark and then aligning the plurality of second alignment marks AM2 based on the same third alignment mark, errors due to, for example a plurality of alignment and correction procedures, may occur. In contrast, as a feature of embodiments of the present disclosure, in the case of positioning the first workpiece P1 and then performing alignment by correcting a position of the second workpiece P2 based on the first workpiece P1, a number of procedures of alignment and corrections may be reduced and a reduction in errors may be achieved.

Referring to FIGS. 3 and 4G, the process 101 of manufacturing a display panel or the method of manufacturing a display panel may include bonding the first workpiece P1 and the second workpiece P2 to each other. In an embodiment, the first workpiece P1 and the second workpiece P2 may be bonded to each other after being aligned according to predetermined or pre-designed relative positions.

In an embodiment, with the alignment of the first workpiece P1 and the second workpiece P2 maintained, the second workpiece P2 may rise along with the second stage 231 to be brought into direct contact with the first workpiece P1. In an embodiment, the second workpiece P2 may rise along the z-axis and directly contact the first workpiece P1 while maintaining alignment with the first workpiece P1, e.g., maintaining position in the xy plane.

In an embodiment, with the direct contact of the first workpiece P1 and the second workpiece P2 maintained, the bonding element 215 may bond the first workpiece P1 and the second workpiece P2 to each other. In an embodiment, the bonding element 215 may reciprocate between the front end 21a and the back end 21b of the bonding portion 21 and apply pressure to the first workpiece P1, the second workpiece P2, and the adhesive layer AL (refer to FIG. 4D) between the first workpiece P1 and the second workpiece P2 with at least one roller. The first workpiece P1 and the second workpiece P2 may be bonded (e.g., adhered) to each other via the adhesive layer AL. In an embodiment, while the bonding element 215 applies pressure to the supporting element 216 and the first workpiece P1 to compress the first workpiece P1, the adhesive layer AL and the second workpiece P2 together to bond the first workpiece P1 and the second workpiece P2 to each other, the second stage 231 may fasten the second workpiece P2 in place.

In an embodiment, the image-capturing element 214 and the bonding element 215 may both be built into (e.g., integrated in) the bonding portion 21, and the above-mentioned alignment process and bonding process of the first workpiece P1 and the second workpiece P2 may be performed in the bonding portion 21.

As a comparative example, in a case of an embodiment in which alignment and bonding of the first workpiece P1 and the second workpiece P2 are performed in different spaces, for example, in a case in which alignment is performed outside the bonding portion 21 and the first workpiece P1 and the second workpiece P2 are (e.g., separately) introduced into the bonding portion 21 and are bonded, errors due to, for example a moving process, may occur. In contrast, as a feature of the present disclosure, in the case of performing alignment and bonding of the first workpiece P1 and the second workpiece P2 in a same space, e.g., in the bonding portion 21, errors may be reduced since bonding may be performed directly after alignment without unnecessary movements (e.g., displacements).

Referring to FIGS. 3 and 4H, in an embodiment the process 101 of manufacturing a display panel or the method of manufacturing a display panel may include peeling the bonded first workpiece P1 and second workpiece P2 from the supporting element 216.

In an embodiment, due to the presence of the adhesive layer AL (refer to FIG. 4D), a bonding force between the first workpiece P1 and the second workpiece P2 may be larger than a bonding force between the first workpiece P1 and the supporting element 216. Therefore, when force is applied to the bonded first workpiece P1 and the second workpiece P2 (e.g., in a -z-axis direction), peeling may occur between the first workpiece P1 and the supporting element 216. In an embodiment, the device 2 for manufacturing a display panel may include any suitable means (e.g., a robot arm or a structure of the second stage 231 gripping the second workpiece P2) for applying such force. The first workpiece P1 and second workpiece P2, bonded together and peeled off from the supporting element 216, may be sent to a subsequent process.

FIG. 5 is a block diagram of an electronic device according to an embodiment.

Referring to FIG. 5, an electronic device 10 may include a display panel 11, a processor 12, a memory 13, and a power module 14. In an embodiment, the display panel 11 may be manufactured by using the device 2 for manufacturing a display panel or the method of manufacturing a display panel described above.

The processor 12 may include at least one of a central processing unit (CPU), an application processor (AP), a graphics processing unit (GPU), a communication processor (CP), an image signal processor (ISP), and a controller. In an embodiment, the processor 12 may be divided into two or more processors, from a functional or structural point of view. For example, the processor 12 may include a main processor as a first driving chip including a CPU, and an auxiliary processor as a second driving chip including a controller that receives an image signal from the main processor and processes the image signal to meet interface specifications of the display panel 11.

The memory 13 may include at least one of a nonvolatile memory and a volatile memory. The memory 13 may store data information necessary for an operation of the processor 12 or the display panel 11. When the processor 12 executes an application stored in the memory 13, an image data signal and/or an input control signal may be transmitted to the display panel 11, and the display panel 11 may process the received signal and may output image information through a display screen.

The power module 14 may include a power supply module, such as a power adaptor or a battery device, and a power conversion module configured to convert power supplied by the power supply module and generate power necessary for an operation of the electronic device 10. Power conversion by the power conversion module may include, but is not necessarily limited to, direct current (DC)-DC conversion, alternating current (AC)-DC conversion, and DC-AC conversion.

The electronic device 10 may further include an input module 15, a non-image output module 16, and/or a communication module 17.

The input module 15 may provide input information to the processor 12 and/or the display panel 11. The input module 15 may include not only a physical button, a keyboard, and a microphone but also various sensor modules. Examples of the sensor modules may include not only a touch sensor, a pressure sensor, a distance sensor, a position sensor, a digitizer, a motion recognition sensor, a camera sensor, a light reception sensor, a photoelectric conversion sensor, and a temperature sensor, but also biometric sensors such as a blood pressure sensor, a blood sugar sensor, an electrocardiogram sensor, and a heart rate sensor.

The non-image output module 16 may receive information other than an image received from the processor 12 and may provide the information to a user. Examples of the non-image output module 16 may include a sound module, a haptic module, and a light-emitting module, and may also include other functionally intrinsic modules (e.g., a cooling module of a refrigerator) of an electronic device.

The communication module 17 is a module for transmitting/receiving information between the electronic device 10 and an external device, and may include a receiver and a transmitter. The communication module 17 may include various wireless communication modules, such as a mobile communication module, a Wi-Fi module, and a Bluetooth module, or various wired communication modules.

At least one of the components of the electronic device 10 described above may be included in a display apparatus. Also, some of individual modules functionally included in one module may be included in the display apparatus and the others may be provided separately from the display apparatus. For example, the display apparatus may include the display panel 11, and the processor 12, the memory 13, and the power module 14 may be provided as other devices in the electronic device 10, rather than the display apparatus. In another example, the power module 14 may be provided in the display apparatus, and may supply power to the processor 12 and the memory 13 provided in the electronic device 10, rather than the display apparatus. However, embodiments of the present disclosure are not necessarily limited thereto.

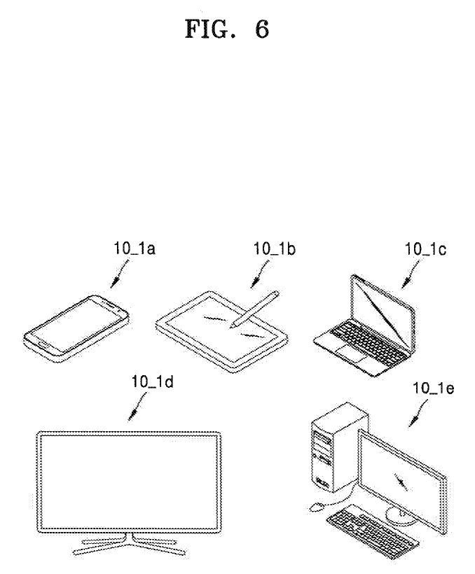

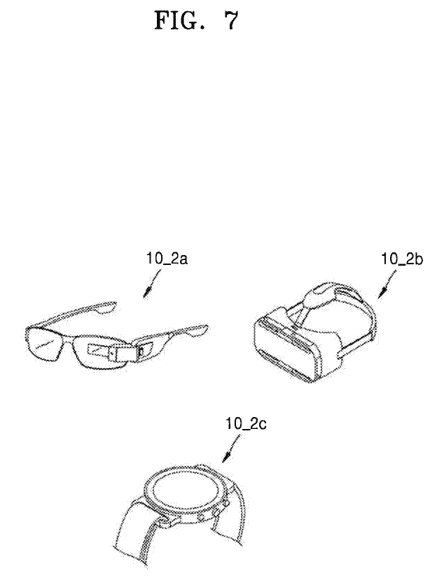

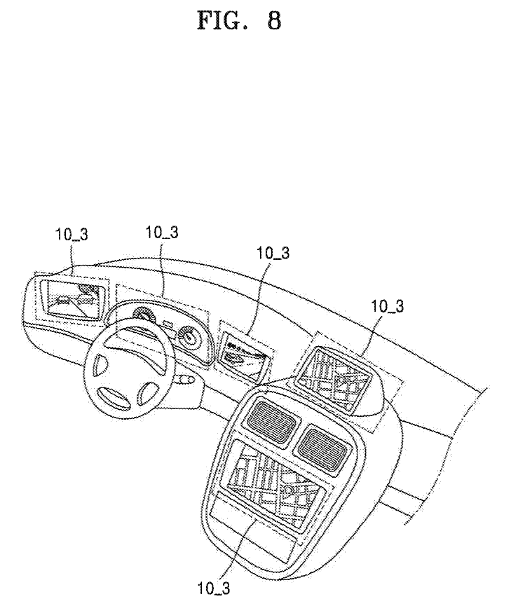

FIGS. 6 to 8 are schematic views illustrating electronic devices according to various embodiments. FIGS. 6 to 8 illustrate examples of various electronic devices to which a display apparatus is applied according to embodiments.

FIG. 6 illustrates a smartphone 10_1a, a tablet PC 10_1b, a laptop computer 10_1c, a television 10_1d, and a monitor 10_1e for a desk as examples of an electronic device.

The smartphone 10_1a may include an input module, such as a touch sensor, and a communication module, in addition to a display panel. The smartphone 10_1a may process information received through the communication module or other input modules and may display the information through the display panel of the display apparatus.

Each of the tablet PC 10_1b, the laptop computer 10_1c, the television 10_1d, and the monitor 10_1e for a desk may also include a display panel and an input module, like the smartphone 10_1a, and may further include a communication module when necessary.

FIG. 7 illustrates a case where an electronic device including a display panel is applied to a wearable electronic device. Examples of the wearable electronic device may include smart glasses 10_2a, a head-mounted display 10_2b, and a smart watch 10_2c.

The smart glasses 10_2a and the head-mounted display 10_2b may include a display panel that emits a display image and a reflector that reflects the emitted display screen and provides the display screen to a user’s eyes, thereby providing a screen of virtual reality or augmented reality to the user.

The smart watch 10_2c may include a biometric sensor as an input device, and may provide biometric information recognized through the biometric sensor to the user through a display panel.

FIG. 8 illustrates a case where an electronic device including a display panel is applied to a vehicle. For example, an electronic device 10_3 may be applied to a dashboard or a center fascia of a vehicle, or may be applied to a center information display (CID) disposed on a dashboard of a vehicle or a room mirror display that replaces a side-view mirror.

However, examples of an electronic device to which a display apparatus according to embodiments is applied may include not only devices that mainly display screens, such as an advertisement board, an electronic display board, and a game console, but also various home appliances that display information through a display panel, such as a refrigerator, a washing machine, a drier, an air conditioner, and a robot cleaner. Also, when a display panel has a function of transmitting light, the display panel may be applied to an electronic device such as a smart window or a transparent display apparatus that displays both a background and a display image. Types of an electronic device according to an embodiment are not limited to the examples described above, and various other small-sized, medium-sized and large-sized electronic devices may also be provided.

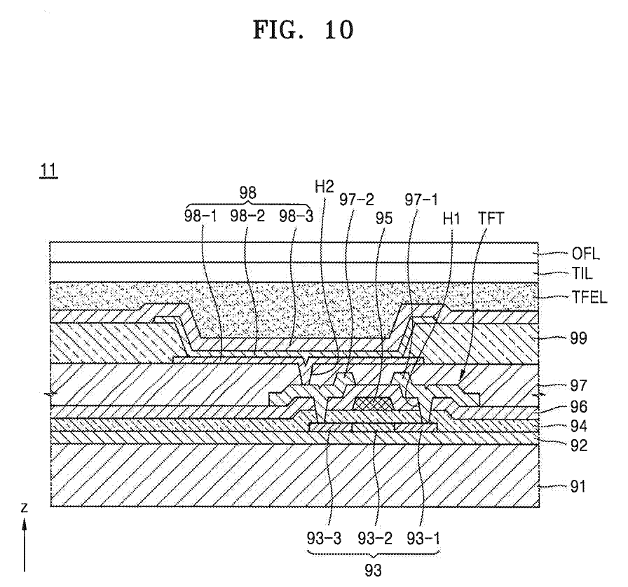

FIG. 9 is a schematic plan view illustrating an electronic device according to an embodiment. FIG. 10 is a cross-sectional view of a display panel according to an embodiment.

Although the electronic device 10 of FIG. 9 is a smartphone, embodiments of the present disclosure are not necessarily limited thereto. The electronic device 10 may include the display panel 11 and a housing 19. In an embodiment, the display panel 11 may be accommodated in the housing 19. The housing 19 is not implemented only as the type illustrated in FIG. 9, and any embodiment may correspond to the housing 19 described in the present disclosure without being limited in type or shape as long as it provides a space in which the display panel 11 may be accommodated.

Referring to FIGS. 9 and 10, a display area DA and a peripheral area PA outside the display area DA may be defined on a substrate 91 of the display panel 11. In the display area DA, a light-emitting diode 98 may be disposed, and in the peripheral area PA, a power supply wiring may be disposed.

In the display area DA, a plurality of deposition material patterns may be disposed. Although the display panel 11 and the display area DA have substantially quadrangular shapes in FIG. 9, embodiments of the present disclosure are not necessarily limited thereto. The display panel 11 and/or the display area DA may have another shape, for example, an irregular shape.

In an embodiment, the display panel 11 may include the substrate 91, a thin-film transistor TFT disposed on the substrate 91, and the light-emitting diode 98 disposed on the thin-film transistor TFT. The light-emitting diode 98 may be electrically connected to a thin-film transistor TFT.

In an embodiment, the substrate 91 may include a plastic material or a metal material. In an embodiment, the substrate 91 may include polyimide (PI). The thin-film transistor TFT may be disposed on the substrate 91, a via layer 97 may be disposed to cover the thin-film transistor TFT, and the light-emitting diode 98 may be disposed on the via layer 97.

A buffer layer 92 including an inorganic insulating material may be disposed on a top surface of the substrate 91. In an embodiment, the buffer layer 92 may include silicon oxide (SiO₂), silicon nitride (SiNₓ), and/or silicon oxynitride (SiON).

An active layer 93 may be disposed in a certain pattern on the buffer layer 92, and the active layer 93 may be covered by a gate insulating layer 94. The active layer 93 may have a source region 93-1 and a drain region 93-3 and may have a channel region 93-2 between the source region 93-1 and the drain region 93-3.

The active layer 93 may be formed of various materials. In an embodiment, the active layer 93 may include an inorganic semiconductor material such as amorphous silicon or crystalline silicon. In an embodiment, the active layer 93 may include an oxide semiconductor. In an embodiment, the active layer 93 may include an organic semiconductor material.

The active layer 93 may be formed by forming an amorphous silicon film on the buffer layer 92, crystallizing the amorphous silicon film to form a polycrystalline silicon film, and patterning the polycrystalline silicon film. In the active layer 93, the source region 93-1 and the drain region 93-3 may be doped with impurities.

A gate electrode 95 corresponding to the active layer 93 and an interlayer insulating layer 96 covering the gate electrode 95 may be disposed on a top surface of the gate insulating layer 94. After a contact hole H1 is formed in the interlayer insulating layer 96 and the gate insulating layer 94, a source electrode 97-1 and a drain electrode 97-2 may be disposed on the interlayer insulating layer 96 to respectively contact the source region 93-1 and the drain region 93-3.

The via layer 97 may be disposed on the thin-film transistor TFT, and a pixel electrode 98-1 of the light-emitting diode 98 may be disposed on the via layer 97. The pixel electrode 98-1 may contact the drain electrode 97-2 of the thin-film transistor TFT through a via hole H2 formed in the via layer 97. The via layer 97 may include an inorganic material and/or an organic material and may have a single or multi-layer structure. The via layer 97 may be formed as a planarization film so that a top surface thereof is flat regardless of a curvature of a lower film, or may be formed to be curved along a curvature of a lower film.

After the pixel electrode 98-1 is disposed on the via layer 97, a pixel-defining film 99 may be formed to cover the pixel electrode 98-1 and the via layer 97, and the pixel-defining film 99 may be open to expose a part of the pixel electrode 98-1.

An intermediate layer 98-2 and a counter electrode 98-3 may be disposed on the pixel electrode 98-1. The counter electrode 98-3 may be disposed on the intermediate layer 98-2 and the pixel-defining film 99. In an embodiment, the counter electrode 98-3 may be disposed on an entire surface of the substrate 91.

The intermediate layer 98-2 may include an emission layer. In an embodiment, the intermediate layer 98-2 may include the emission layer, and may further include at least one of a hole injection layer, a hole transport layer, an electron transport layer, and an electron injection layer. Embodiments of the present disclosure is not necessarily limited thereto, and the intermediate layer 98-2 may include the emission layer and may further include various other functional layers.

The pixel electrode 98-1 and the counter electrode 98-3 may be insulated from each other by the intermediate layer 98-2. Voltages of different polarities may be applied to the intermediate layer 98-2 by the pixel electrode 98-1 and the counter electrode 98-3 so that the emission layer included in the intermediate layer 98-2 emits light.

A plurality of intermediate layers 98-2 may be provided, and the plurality of intermediate layers 98-2 may form the display area DA. In this case, the plurality of intermediate layers 98-2 may be spaced apart from each other in the display area DA.

A thin-film encapsulation layer TFEL may include a plurality of inorganic layers or may include an inorganic layer and an organic layer. The organic layer of the thin-film encapsulation layer TFEL may be formed of a polymer, and may preferably have a single or multi-layer structure including any one of polyethylene terephthalate, polyimide, polycarbonate, epoxy, polyethylene, and polyacrylate. The inorganic layer of the thin-film encapsulation layer TFEL may have a single or multi-layer structure including a metal oxide or a metal nitride. For example, in an embodiment the inorganic layer may include any one of silicon oxide (SiO₂), silicon nitride (SiNₓ), silicon oxynitride (SiON), aluminum oxide (Al₂O₃), and titanium oxide (TiO₂). An uppermost layer exposed to the outside among layers of the thin-film encapsulation layer TFEL may be an inorganic layer to prevent moisture penetration into the light-emitting diode 98.

The thin-film encapsulation layer TFEL may include at least one sandwich structure in which at least one organic layer is inserted between at least two inorganic layers. In another example, the thin-film encapsulation layer TFEL may include at least one sandwich structure in which at least one inorganic layer is inserted between at least two organic layers. In another embodiment, the thin-film encapsulation layer TFEL may include a sandwich structure in which at least one organic layer is inserted between at least two inorganic layers and a sandwich structure in which at least one inorganic layer is inserted between at least two organic layers.

The touch input layer TIL may be disposed on the thin-film encapsulation layer TFEL. The touch input layer TIL may include a touch sensor configured to sense touch inputs, and a touch insulation layer covering the touch sensor.

The optical function layer OFL may be disposed on the touch input layer TIL. The optical function layer OFL may improve a light-emission efficiency of the light-emitting diode 98. In an embodiment, the optical function layer OFL may include at least one of a light-blocking layer, an overcoating layer, and a polarizing film.

Some of the layers of the above-mentioned display panel 11 may be disposed on the substrate 91 in the form of a film. In this case, the layers provided as films may correspond to the first workpiece P1, and a subject on which the films are disposed (e.g., an unfinished product of the display panel 11 with certain layers disposed on the substrate 91) may correspond to the second workpiece P2.

According one or more embodiments of the present disclosure, a device for manufacturing a display panel including an image-capturing element (e.g., a camera) for alignment provided within a bonding portion in which a first workpiece (e.g., polarizing film) and a second workpiece (e.g., an unfinished product of a display panel) is provided. According to one or more embodiments of the present disclosure, a method of manufacturing a display panel which captures images of, aligns, and bonds the first workpiece and the second workpiece within the bonding portion without unnecessary movement are bonded is provided. Moreover, according to one or more embodiments of the present disclosure, a method of manufacturing an electronic device including the display panel may be provided. Errors which may occur during bonding the first workpiece and the second workpiece to manufacture the display panel may be reduced.

Although one or more non-limiting embodiments have been described with reference to the figures, it will be understood by one of ordinary skill in the art that various changes in form and details may be made therein.

What is claimed is:

1. A device for manufacturing a display panel, the device comprising:
a first moving portion configured to move a first workpiece;
a second moving portion configured to move a second workpiece; and
a bonding portion comprising an image-capturing element configured to capture images of the first workpiece and the second workpiece and a bonding element configured to bond the first workpiece and the second workpiece to each other.

2. The device of claim 1, wherein:
the bonding portion further comprises a supporting element configured to secure the first workpiece.

3. The device of claim 2, wherein:
the supporting element is disposed between the image-capturing element and the first workpiece and transmits light, wherein the image-capturing element captures the images of the first workpiece and the second workpiece utilizing the light transmitted by the supporting element.

4. The device of claim 1, wherein:
the bonding portion is disposed between the first moving portion and the second moving portion.

5. The device of claim 1, wherein:
the bonding element is configured to be movable within the bonding portion.

6. The device of claim 5, wherein:
the image-capturing element is configured to be attached to the bonding element and move with the bonding element.

7. The device of claim 6, wherein:
the image-capturing element and the bonding element are disposed at a front end of the bonding portion and are configured to reciprocate between the front end and a back end of the bonding portion.

8. The device of claim 1, wherein:
the image-capturing element comprises a camera and the bonding element comprises at least one roller.

9. The device of claim 1, further comprising:
a control portion configured to correct a position of the second workpiece relative to the first workpiece based on positions of the first workpiece and the second workpiece in the images of the first workpiece and the second workpiece captured by the image-capturing element.

10. A method of manufacturing a display panel, the method comprising:
moving a first workpiece to a bonding portion;
moving a second workpiece to the bonding portion;
capturing images of the first workpiece and the second workpiece by using an image-capturing element built into the bonding portion;
aligning the first workpiece and the second workpiece with each other by correcting a position of the second workpiece relative to the first workpiece; and
bonding the first workpiece and the second workpiece to each other by using a bonding element built into the bonding portion while maintaining alignment positions of the aligned first workpiece and second workpiece.

11. The method of claim 10, wherein:
the bonding portion further comprises a supporting element disposed between the image-capturing element and the first workpiece; and
the supporting element transmits light such that the image-capturing element may capture the images of the first workpiece and the second workpiece.

12. The method of claim 11, further comprising:
securing the first workpiece on a surface of the supporting element.

13. The method of claim 12, further comprising:
exposing an adhesive layer by removing a release film provided on a surface of the first workpiece secured on the first supporting element.

14. The method of claim 13, wherein:
in the bonding of the first workpiece and the second workpiece to each other, the first workpiece, the adhesive layer of the first workpiece, and the second workpiece are compressed together.

15. The method of claim 14, further comprising:
peeling the bonded first workpiece and second workpiece from the supporting element.

16. The method of claim 10, wherein:
in the capturing images of the first workpiece and the second workpiece, the image-capturing element is positioned at a front end of the bonding portion to capture the images of the first workpiece and the second workpiece.

17. The method of claim 16, wherein:
the bonding element is configured to reciprocate between the front end and a back end of the bonding portion.

18. The method of claim 17, wherein:
the image-capturing element is configured to be attached to the bonding element and move with the bonding element.

19. The method of claim 10, wherein:
the aligning of the first workpiece and the second workpiece with each other and the bonding the first workpiece and the second workpiece to each other are performed in the bonding portion.

20. A method of manufacturing an electronic device, the method comprising:
manufacturing a display panel; and
bonding the display panel with a processor; wherein
the manufacturing of the display panel comprises:
moving a first workpiece to a bonding portion;
moving a second workpiece to the bonding portion;
capturing images of the first workpiece and the second workpiece by using an image-capturing element built into the bonding portion;
aligning the first workpiece and the second workpiece with each other by correcting a position of the second workpiece relative to the first workpiece; and
bonding the first workpiece and the second workpiece to each other by using a bonding element built into the bonding portion while maintaining alignment positions of the aligned first workpiece and second workpiece.
